(19) United States
(12) Patent Application Publication
(10) Pub. No.: US 2024/0204015 A1
(43) Pub. Date: Jun. 20, 2024

(54) IMAGE SENSOR

(71) Applicant: Samsung Electronics Co., Ltd., Suwon-si (KR)

(72) Inventors: Daehyung Lee, Suwon-si (KR); Kwanyoung Oh, Suwon-si (KR)

(21) Appl. No.: 18/309,347

(22) Filed: Apr. 28, 2023

(30) Foreign Application Priority Data
Dec. 16, 2022 (KR) 10-2022-0177007

(51) Int. Cl. H01L 27/146

(52) U.S. Cl. CPC H01L 27/14614; H01L 27/14627; H01L 27/1463; H01L 27/1464; H01L 27/14645

(57) ABSTRACT

An image sensor includes at least one pixel, and the pixel includes a photoelectric conversion region in a semiconductor substrate having a first surface and a second surface, a floating diffusion region spaced apart from the photoelectric conversion region in the semiconductor substrate, and a vertical transfer gate that extends into the semiconductor substrate from the first surface of the semiconductor substrate. A transfer channel is between the photoelectric conversion region and the floating diffusion region.

### CROSS-REFERENCE TO RELATED APPLICATION(S)

This application claims benefit of priority to Korean Patent Application No. 10-2022-0177007, filed on Dec. 16, 2022, in the Korean Intellectual Property Office, the disclosure of which is incorporated herein by reference in its entirety.

### BACKGROUND

The present disclosure relates to an image sensor, and more particularly, to an image sensor including a photodiode.

An image sensor converts optical image signals into electrical signals and includes a charge-coupled device (CCD) image sensor, a complementary metal oxide semiconductor (CMOS) image sensor, or the like.

Such an image sensor includes a plurality of pixels. Each of the plurality of pixel includes a photodiode region, in which incident light is received and converted into an electrical signal, and a pixel circuit outputting pixel signals using charges generated in the photodiode region. As the degree of integration of an image sensor increases, a size of each pixel decreases. Image transmission delay, or the like, occurs depending on the arrangement and shapes of components in a pixel for implementing a decrease in size, resulting in deterioration in the quality of an image sensor.

### SUMMARY

Example embodiments provide a high-quality image sensor having improved image transmission capability.

According to example embodiments, an image sensor includes at least one pixel. The pixel may include a photoelectric conversion region in a semiconductor substrate that has a first surface and a second surface that oppose each other, a floating diffusion region spaced apart from the photoelectric conversion region in the semiconductor substrate, and a vertical transfer gate that extends into the semiconductor substrate from the first surface of the semiconductor substrate, and a transfer channel between the photoelectric conversion region and the floating diffusion region. The vertical transfer gate may have an annular shape along a periphery of the floating diffusion region in plan view, and may have an opening that is in a charge transfer path from the photoelectric conversion region to the floating diffusion region.

In example embodiments, the opening may be provided to overlap a straight line connecting the floating diffusion region to a point, representing a maximum potential value, in the photoelectric conversion region.

In example embodiments, the vertical transfer gate may have a circular or rectangular annular shape.

In example embodiments, the photoelectric conversion region may receive incident light through the second surface of the semiconductor substrate.

In example embodiments, an image sensor includes a pixel array including a plurality of pixels, and a control unit configured to control the pixel array. Each of the plurality of pixels includes a photoelectric conversion region in a semiconductor substrate that has a first surface and a second surface that oppose each other, a floating diffusion region spaced apart from the photoelectric conversion region in the semiconductor substrate, and a vertical transfer gate that extends into the semiconductor substrate from the first surface of the semiconductor substrate. A transfer channel is between the photoelectric conversion region and the floating diffusion region. The vertical transfer gate has an annular shape along a periphery of the floating diffusion region in plan view. The vertical transfer gate has an opening that is in a charge transfer path from the photoelectric conversion region to the floating diffusion region.

In example embodiments, an image sensor includes a pixel including a photoelectric conversion region in a semiconductor substrate, a floating diffusion region that extends into the semiconductor substrate, and a vertical transfer gate that partially surrounds the floating diffusion region in plan view. The floating diffusion region is spaced apart from the photoelectric conversion region.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a layout diagram illustrating an image sensor according to example embodiments.

FIG. 2 is a plan view illustrating a single pixel in FIG. 1.

FIG. 3A is a cross-sectional view taken along line A-A′ of FIG. 2, and FIG. 3B is a cross-sectional view taken along line B-B′ of FIG. 2.

FIG. 4A is a plan view illustrating a pixel of an image sensor, and FIG. 4B is a cross-sectional view taken along line C-C′ of FIG. 4A.

FIG. 5 is a graph illustrating a potential level of a charge transfer path in a pixel of an image sensor in example embodiments.

FIG. 6A is a plan view illustrating that a shape of a vertical transfer gate is formed to be different from that in the above-described embodiment when viewed on a plane, and FIG. 6B is a cross-sectional view taken along line D-D′ of FIG. 6A.

FIG. 7 is a diagram illustrating a plurality of pixels corresponding to a region P1 of FIG. 1 and illustrating an example in which each of the pixels includes an additional transistor, or the like.

FIG. 8 is a cross-sectional view taken along line E-E′ of FIG. 7.

FIG. 9 is an equivalent circuit diagram of a pixel of an image sensor according to example embodiments.

FIG. 10 is a plan view illustrating an image sensor according to example embodiments.

FIG. 11A is a plan view illustrating an image sensor according to example embodiments, and FIG. 11B is a cross-sectional view taken along line F-F′ of FIG. 11A.

FIG. 12 is a plan view illustrating an image sensor according to example embodiments.

FIG. 13 is a block diagram illustrating a configuration of an image sensor according to example embodiments.

### DETAILED DESCRIPTION

Hereinafter, example embodiments will be described with reference to the accompanying drawings.

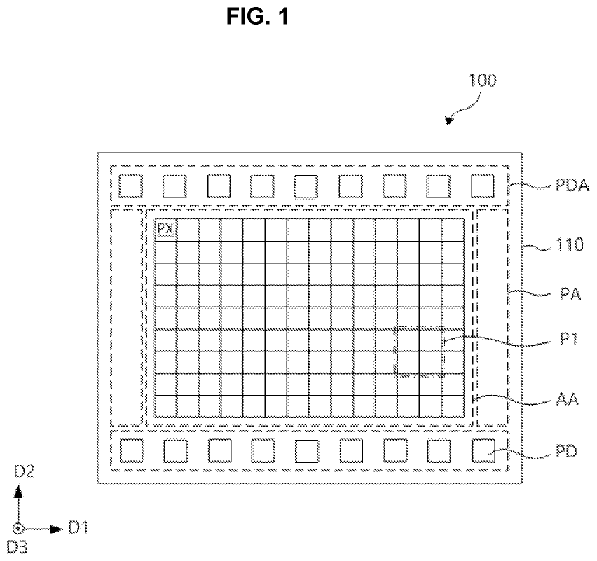

FIG. 1 is a layout diagram illustrating an image sensor according to example embodiments.

Referring to FIG. 1, an image sensor 100 according to example embodiments may include a semiconductor substrate 110 having an active region AA, a peripheral region PA, and a pad region PDA.

The semiconductor substrate 110 may have a first surface 110F and a second surface 110R opposing the first surface 110F. In example embodiments, the first surface 110F may be a front surface, and the first surface 110F may be a rear surface. However, example embodiments are not limited thereto, and the first and second surfaces 110F and 110R may be set to vary depending on an arrangement of image sensors.

The image sensor according to example embodiments may receive external light through a rear surface of the semiconductor substrate 110, for example, the second surface 110R to perform photoelectric conversion. In this case, a vertical transfer gate VTG to be described later or another transistor may be formed on the first surface 110F of the semiconductor substrate 110, and incident light may reach a photoelectric conversion region PD through the second surface 110R of the semiconductor substrate 110.

In example embodiments, the semiconductor substrate 110 may be formed of a semiconductor material, for example, silicon (Si), germanium (GE), silicon-germanium (SiGe), silicon carbide (SiC), gallium arsenide (GaAs), indium arsenide (InAs), indium phosphide (InP), or the like. The semiconductor substrate 110 may be a semiconductor substrate 110 doped with predetermined impurities. For example, the semiconductor substrate 110 may be a first conductivity-type (for example, P-type) silicon substrate. In example embodiments, the semiconductor substrate 110 may include a semiconductor layer formed through an epitaxial process. For example, the semiconductor substrate 110 may include a P-type bulk substrate and a P-type or N-type epitaxial layer grown thereon. In some embodiments, the semiconductor substrate 110 may include an N-type bulk substrate and a P-type or N-type epitaxial layer grown thereon. However, a material of the semiconductor substrate 110 is not limited thereto, and the substrate may include an organic polymer substrate or other types of substrates.

An image sensor according to example embodiments may include at least one pixel PX for photoelectric conversion, and the active region AA may correspond to a region in which the pixels PX are provided. The active region AA may be disposed in a central portion of the semiconductor substrate 110. A plurality of pixels PX may be provided in a matrix in the active region AA. For example, when one direction of the image sensor is referred to a first direction D1 (or an X-direction) and another direction, perpendicular to the first direction D1, is referred to as a second direction D2 (or a Y-direction), the plurality of pixels PX may be arranged in a matrix of rows and columns in the first direction D1 and the second direction D2. A third direction D3, which is not described, refers to a direction, perpendicular to the first and second directions D1 and D2.

The peripheral region PA may be disposed adjacent to the active region AA and disposed on at least one side of the active region AA, for example, opposite sides of the active region AA. A pixel circuit may be disposed in the peripheral region PA to control the pixels PXs in the active region AA. However, the location of the pixel circuit being in the peripheral region PA is not limited thereto, and the peripheral region PA may surround an entirety of the active region AA or may be provided on one side of the active region AA. In some embodiments, the peripheral region PA may be formed on another substrate to be connected in the form of a stack.

The pad region PDA may be provided for connection to other components, for example, other devices, and may be disposed in an edge region in which the active region AA and the peripheral region PA are not provided. The pad region PDA may be provided in a location, different from an illustrated location, for connection to other components. In the pad region PDA, pads may be disposed for electrical/physical connection between the image sensor and other devices.

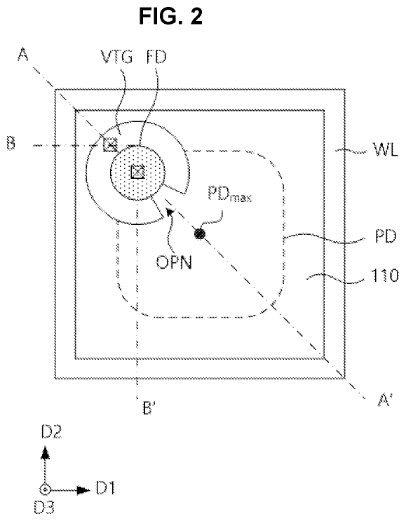

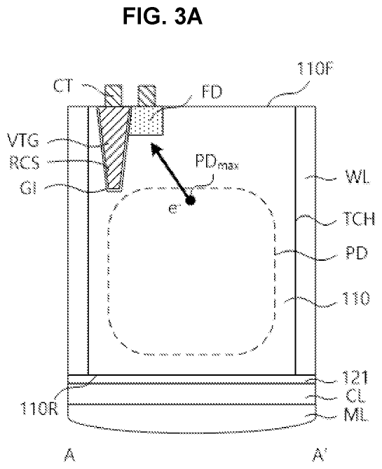

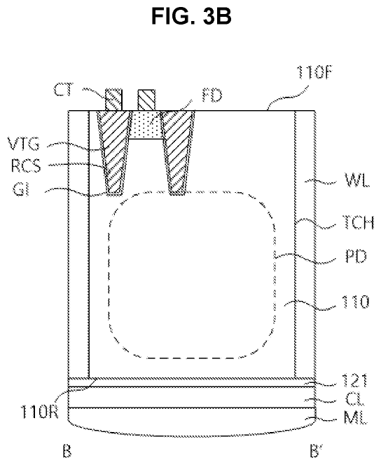

FIG. 2 is a plan view illustrating a single pixel in FIG. 1, FIG. 3A is a cross-sectional view taken along line A-A′ of FIG. 2, and FIG. 3B is a cross-sectional view taken along line B-B′ of FIG. 2.

Referring to FIGS. 1, 2, 3A, and 3B, the pixel may include a photoelectric conversion region PD formed in a semiconductor substrate 110, a floating diffusion region FD provided to be spaced apart from the photoelectric conversion region PD in the semiconductor substrate 110, and a vertical transfer gate VTG provided between the photoelectric conversion region PD and the floating diffusion region FD.

The photoelectric conversion region PD may be formed in the semiconductor substrate 110, and may generate charges (for example, photocharges) based on received incident light. For example, electron-hole pairs may be formed in response to the incident light, and such electrons or holes may be accumulated in the photoelectric conversion region PD.

The floating diffusion region FD may be provided to be spaced apart from the photoelectric conversion region PD. The floating diffusion region FD extends along a portion of a sidewall of the vertical transfer gate VTG, and a bottom surface of the floating diffusion region VTG may be separated from a bottom surface of the vertical transfer gate VTG. The floating diffusion region FD may be a region in which charges, generated in the photoelectric conversion region PD, are transferred and stored by the vertical transfer gate VTG. The floating diffusion region FD may be a region doped with second conductivity-type (for example, N-type) impurities.

The vertical transfer gate VTG may be formed in a recess RCS extending inwardly of the semiconductor substrate 110 from the first surface 110F of the semiconductor substrate 110.

The vertical transfer gate VTG may form a transfer channel between the photoelectric conversion region PD and the floating diffusion region FD in response to a transmission signal to transfer the charges, generated in the photoelectric conversion region PD, to the floating diffusion region FD. The transfer channel may include a vertical transfer channel adjacent to a side surface of the recess RCS.

The vertical transfer gate VTG may have a gate-all-around structure in which a floating diffusion region FD extends in a vertical direction and a vertical gate electrode surrounds the floating diffusion region FD. For example, the vertical transfer gate VTG may be provided in the form of a hollow cylinder surrounding the floating diffusion region FD along a periphery of the floating diffusion region FD. Accordingly, the vertical transfer gate VTG may have an annular shape when viewed on a plane. For example, the annular shape of the vertical transfer gate VTG may be circular or elliptical when viewed on a plane.

In example embodiments, the vertical transfer gate VTG may be provided to have an overall hollow cylindrical shape (an annular shape when viewed on a plane), but may have an opening OPN opened in one direction.

The opening OPN may be disposed in a charge transfer path from the photoelectric conversion region PD to the floating diffusion region FD. In example embodiments, a transfer path from a point, representing a maximum potential value PDₘₐₓ in the photoelectric conversion region PD, to the floating diffusion region FD serves as a main charge transfer path, so that the charge transfer path may be a path connecting the floating diffusion region FD and the point, representing the maximum potential value PDₘₐₓ in the photoelectric conversion region PD, to each other. For example, the main transfer path may be a straight path connecting an arbitrary point of the floating diffusion region FD to the point representing the maximum potential value PDₘₐₓ in the photoelectric conversion region PD, or a straight path connecting a center of the floating diffusion region FD and the point, representing the maximum potential value PDₘₐₓ in the photoelectric conversion region PD, to each other.

In example embodiments, the opening OPN may be provided in a direction, opposite to the maximum potential value PDₘₐₓ in the photoelectric conversion region PD from the floating diffusion region FD. In example embodiments, the opening OPN may overlap a straight line connecting the floating diffusion region FD to the point, representing the maximum potential value PDₘₐₓ, in the photoelectric conversion region PD. A straight line connecting the floating diffusion region FD to the point may be the shortest linear distance between the floating diffusion region FD and the point. Accordingly, the opening OPN may include a portion corresponding to the straight line or a portion adjacent to the straight line, and the vertical transfer gate VTG may not be provided in such a portion.

A size and a shape of the opening OPN may be variously modified as long as the charge transfer path is secured. The opening OPN may have a width increasing in a direction toward the floating diffusion region FD, or may maintain the same width. The size of the opening OPN may be reduced to secure a charge transfer path on a straight line as long as an area, in which the vertical transfer gate VTG contacts the floating diffusion region FD, is larger than an area in which the vertical transfer gate VTS does not contact the floating diffusion region FD due to the opening OPN. For example, when the vertical transfer gate VTG has a circular donut shape, an opened portion may have a size smaller than 180 degrees with respect to a center of a circle. For example, the opened portion may have a shape in which a portion corresponding to about 120 degrees or less, about 30 degrees or less, about 15 degrees or less, about 10 degrees or less, or even about 5 degrees or less may be cut. In some embodiments, when viewed on a plane, a portion of the vertical transfer gate VTG opposing an external periphery of the floating diffusion region FD may be about 50% or more, for example, about 80% or more, about 90% or more, even about 95% or more of an external periphery of a total floating diffusion region FD.

A gate insulating layer GI may be provided on the first surface 110F of the semiconductor substrate 110 and between the vertical transfer gate VTG and the semiconductor substrate 110. The gate insulating layer GI may be formed along a surface of the recess RCS. The gate insulating layer GI may electrically insulate the semiconductor substrate 110 and the vertical transfer gate VTG from each other.

A contact portion CT, connected to an interconnection, may be provided on the vertical transfer gate VTG. For ease of description, the vertical transfer gate VTG according to example embodiments is illustrated as having a top surface being the same as the first surface 110F of the semiconductor substrate 110, but example embodiments are not limited thereto. In example embodiments, the vertical transfer gate VTG may be formed to have a shape protruding upwardly of the first surface 110F of the semiconductor substrate 110, for example, a T-shape.

In example embodiments, a top surface of the photoelectric conversion region PD is disposed to be higher than a bottom surface of the vertical transfer gate VTG, so that at least a portion of the vertical transfer gate VTG may be formed in the photoelectric conversion region PD. However, the disposition of the photoelectric conversion region PD and the vertical transfer gate VTG is not limited thereto, and other dispositions thereof may be applied. In addition, FIGS. 3A and 3B illustrate examples in which the photoelectric conversion region PD is spaced apart from the second surface 110R of the semiconductor substrate 110, but in some embodiments, the photoelectric conversion region PD may extend to the second surface 110R of the semiconductor substrate 110.

In example embodiments, a pixel may be further provided with a rear insulating layer 121, a color filter CF, and a microlens ML.

The color filter CF may be formed to correspond to the photoelectric conversion region PD on the second surface 110R of the semiconductor substrate 110. The color filter CF may be included in an array of color filters CF arranged in a matrix. In some embodiments, the array of color filters CF may have a Bayer pattern including a red filter, a green filter, and/or a blue filter. In some embodiments, the array of color filters CF may include a yellow filter, a magenta filter, and/or a cyan filter. The array of color filters CF may additionally include a white filter. According to example embodiments, an anti-reflection layer, at least one insulating layer, or the like, may be further formed between the second surface 110R of the semiconductor substrate 110 and the color filter CF.

The rear insulating layer 121 may be provided between the color filter CF and the second surface 110R of the semiconductor substrate 110.

The microlens ML may be provided on the color filter CF, and may formed to correspond to the photoelectric conversion region PD. The microlens ML may adjust a path of incident light, incident on the microlens ML, such that the incident light may be focused on the photoelectric conversion region PD. Also, the microlenses ML may be included in an array of microlenses ML arranged in a matrix.

In example embodiments, a pixel region in which each pixel PX is provided and a pixel according thereto may be defined by a separation layer WL. The separation layer WL may electrically and physically separate one of the plurality of photoelectric conversion regions PD from a photoelectric conversion region PD adjacent thereto.

For example, the separation layer WL may be disposed between a plurality of pixels PX arranged in a matrix and may have a grid or mesh shape corresponding to the arrangement of the pixels PX when viewed on a plane. The separation layer WL may be formed in a trench TCH penetrating from the first surface 110F of the semiconductor substrate 110 to the second surface 110R of the semiconductor substrate 110.

The separation layer WL may extend in a direction from the first surface 110F to the second surface 110R of the semiconductor substrate 110, and may penetrate through the first and second surfaces 110F and 110R of the semiconductor substrate 110 or may be provided to have a predetermined depth even when the separation layer WL does not penetrate therethrough. The separation layer WL may surround at least a portion of the periphery of the pixel PX when viewed on a plane.

An image sensor having the above-described structure may lower a potential barrier during movement of electrons while having a gate having a gate-all-around structure to facilitate a flow of the electrons, and thus a high-quality image sensor may be provided.

This will be described with accompanying drawings, as follows.

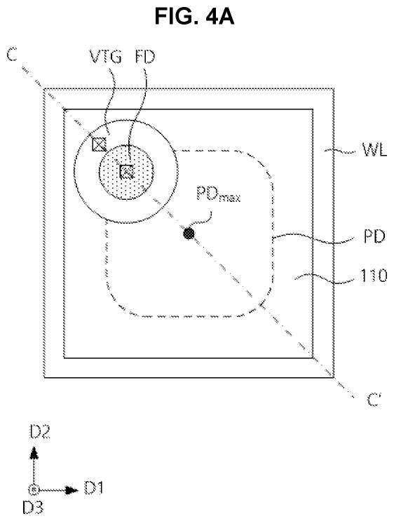

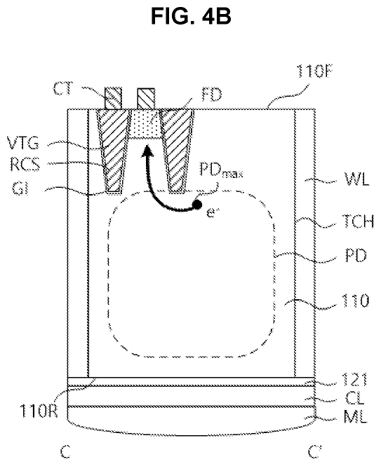

FIG. 4A is a plan view illustrating a pixel of an image sensor, and FIG. 4B is a cross-sectional view taken along line C-C′ of FIG. 4A.

When comparing the pixel of the image sensor according to example embodiments illustrated in FIGS. 2 and 3A with the pixel of the image sensor illustrated in FIGS. 4A and 4B, it can be seen that there is a difference in a transfer path of electrons depending on presence of an opening OPN in terms of a shape of a vertical transfer gate VTG.

When charges generated in a photoelectric conversion region PD move to a floating diffusion region FD, a vertical transfer gate VTG may be disposed on a charge transfer path to delay the movement of the charges. This may result from a physical shape itself of the vertical transfer gate VTG, but may result from impurities (for example, first conductivity-type/P-type impurities) implanted onto a semiconductor substrate 110 during formation of the vertical transfer gate VTG.

Although not illustrated, an impurity region formed by implanting first conductivity-type (for example, P-type) may be provided between a gate insulating layer GI and the semiconductor substrate 110, for example, in the vicinity of a surface of a recess RCS of the semiconductor substrate 110 adjacent to the vertical transfer gate VTG. In a process of forming a recess RCS for the vertical transfer gate VTG, first conductivity-type impurities may be implanted after etching. As a result, an impurity region may be provided in the vicinity of the recess RCS. Due to the first conductivity-type impurities, a potential barrier may be formed in a charge transfer path. The presence of the potential barrier may result in a delay of charge transfer from the photoelectric conversion region to the floating diffusion region.

However, in example embodiments, an opening OPN may be provided in a portion corresponding to a main transfer path of charges.

The opening OPN according to example embodiments may remove the above-described potential barrier when charges are transferred from a point presenting a maximum potential value PDₘₐₓ in a conversion region, for example, a point at which the amount of charges is maximum, to the floating diffusion region FD. Thus, efficient transfer of the charges from the photoelectric conversion region PD to the floating diffusion region FD may be significantly secured.

The point, representing the maximum potential value PDₘₐₓ of the photoelectric conversion region PD, may vary depending on the amount of impurity doped in the photoelectric conversion region PD or a shape, an area, or the like, of the photoelectric conversion region PD, but may correspond to a central portion of the photoelectric conversion region PD when viewed on a plane. In addition, the point representing the maximum potential value PDₘₐₓ may be disposed on an upper side of the photoelectric conversion region PD, for example, between an upper edge and a central portion of the photoelectric conversion region PD when viewed on a plane. The degree of generation of charges in the photoelectric conversion region PD may vary depending on a concentration of impurities (for example, second conductivity-type/N-type impurities), and the concentration of the impurities may be relatively high in an upper portion of the photoelectric conversion region PD. Accordingly, the point representing the maximum potential value PDₘₐₓ of the photoelectric conversion region PD may refer to a point at which the concentration of the impurities is highest.

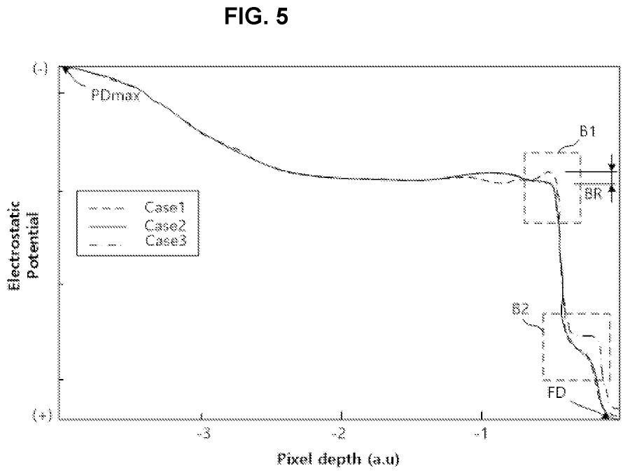

FIG. 5 is a graph illustrating a potential level of a charge transfer path in a pixel of an image sensor in example embodiments. Case 1 represents an image sensor employing a circular vertical transfer gate VTG having a gate-all-around structure, Case 2 represents an image sensor according to example embodiments employing a gate-all-around structure but having an opening in a charge transfer path, and Case 3 represents an image sensor employing a dual gate. Cases 1 to 3 were set under the same conditions, other than a shape of an electrode. Case 1 corresponds to a vertical transfer gate having a circular annular shape when viewed on a plane such as in FIG. 4A, Case 2 corresponds to a vertical transfer gate having a circular annular shape of which one side is open such as in FIG. 2, and Case 3 corresponds to a vertical transfer gate in the case in which dual vertical transfer gates are separated from each other on opposite sides of a charge transfer path and a surface contacting a floating diffusion region FD is less than 50% when viewed on a plane.

Referring to FIG. 5, when a vertical transfer gate was turned on, charges generated in a photoelectric conversion region were transferred to a floating diffusion region along a charge transfer path from the photoelectric conversion region to the floating diffusion region and exhibited a potential as illustrated in the drawing. In the image sensor of Case 1, it can be seen that a potential barrier formed by a vertical transfer gate appears in a region B1. In the image sensor of Case 3, it can be seen that charge transfer is delayed in a region B2. This was determined to be because a portion corresponding to the charge transfer gate was opened, but a contact area between a single floating diffusion region and the vertical transfer gate was small. Meanwhile, in the image sensor of Case 2 corresponding to example embodiments, the potential barrier of Case 1 and the charge transfer delay of Case 3 were not observed.

Through the above description, in a pixel of an image sensor according to example embodiments, a vertical transfer gate is not provided in a region corresponding to a main transfer path of charges while implementing a gate-all-around structure. Therefore, it can be seen that the above-described potential barrier may be removed, transfer characteristics of a vertical transfer gate may be improved, and a transfer delay and an image lag may be prevented. In addition, according to example embodiments, a high full-well capacity and a low transfer gate-on voltage resulting from improvement of charge transfer capability may be secured, and thus a high-quality image sensor may be implemented.

In example embodiments, the vertical transfer gate VTG of the image sensor may be variously modified.

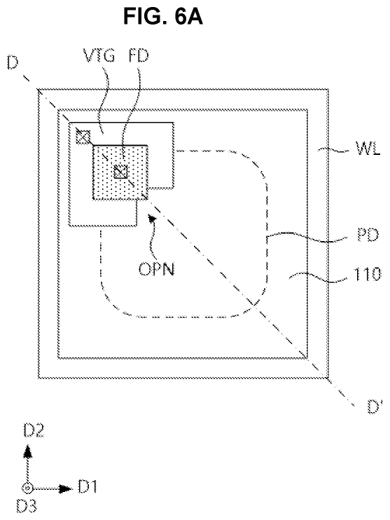

FIG. 6A is a plan view illustrating that a shape of a vertical transfer gate is formed to be different from that in the above-described embodiment when viewed on a plane, and FIG. 6B is a cross-sectional view taken along line D-D′ of FIG. 6A.

Referring to FIGS. 6A and 6B, a vertical transfer gate VTG may have a rectangular ring shape when viewed on a plane.

In the present embodiment, the vertical transfer gate VTG is described as having a rectangular ring shape, but the shape of the vertical transfer gate VTG may be variously modified without departing from the spirit and scope of the present inventive concept. The degree of freedom of design in a pixel may be increased through modification of such a shape of the vertical transfer gate VTG.

An image sensor according to example embodiments may further include additional components other than the above-described components, and may be implemented in various modified examples having a plurality of pixels.

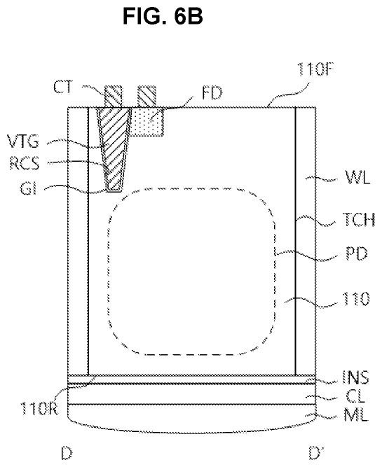

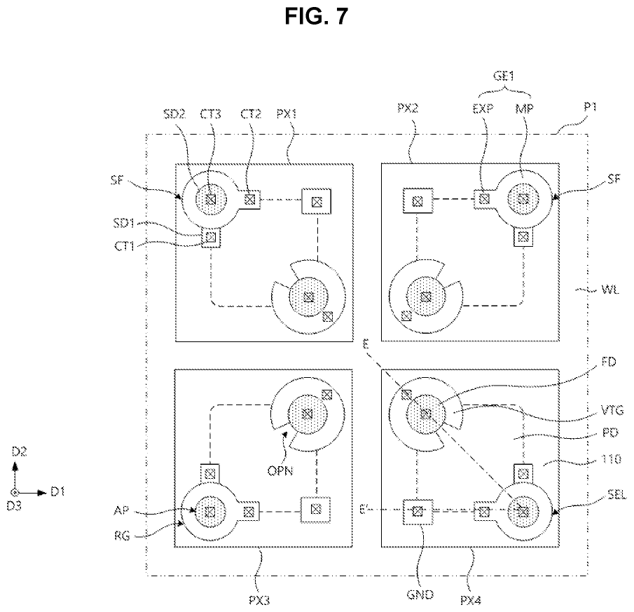

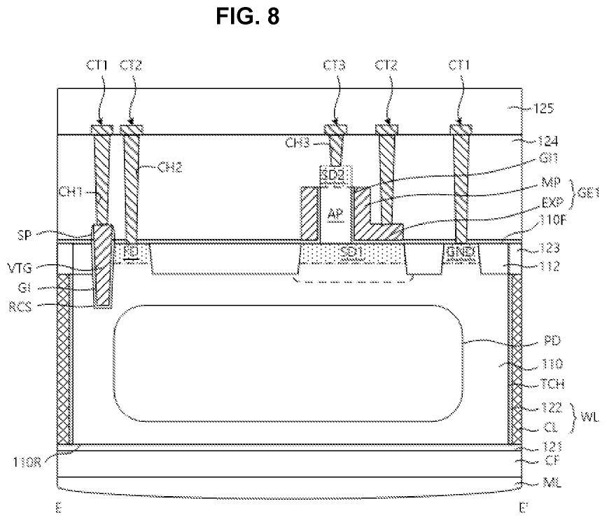

FIG. 7 is a diagram illustrating a plurality of pixels corresponding to a region P1 of FIG. 1 and illustrating an example in which each of the pixels includes an additional transistor, or the like. FIG. 8 is a cross-sectional view taken along line E-E′ of FIG. 7. In FIG. 7, first to fourth pixels PX1, PX2, PX3, and PX4 adjacent to each other are illustrated as an example. In the following embodiments, for ease of description, a description will be provided with respect to main differences from the above descriptions.

Referring to FIGS. 7 and 8, a plurality of pixels, for example, the first pixel PX1, the second pixel PX2, the third pixel PX3, and the fourth pixel PX4 may be disposed on a semiconductor substrate 110 in a matrix. The first to fourth pixels PX1, PX2, PX3, and PX4 may be disposed in various forms. For example, the first to fourth pixels PX1, PX2, PX3, and PX4 may be disposed to have the same shape or to be mirror-symmetrical with each other in row and column directions, for example, a first direction D1 and a second direction D2. In example embodiments, there is illustrated an example in which the first pixel PX1 and the second pixel PX2 disposed side by side in the first direction D1 are mirror-symmetrical with each other, and the first pixel PX1 and the third pixel PX3 disposed side by side in the second direction D2 are mirror-symmetrical with each other.

In example embodiments, each pixel may further include additional components required to drive an image sensor in various manners. For example, each of the first pixel PX1 and the second pixel PX2 may include a transfer gate TG and a source follower gate SF, the third pixel PX3 may include a transfer gate TG and a reset gate RG, and the fourth pixel PX4 may include a transfer gate TG and a select gate SEL. However, this corresponds to a layout of transistors according to some embodiments, and the layout of the transistors or a shape of an active region AA is not limited thereto.

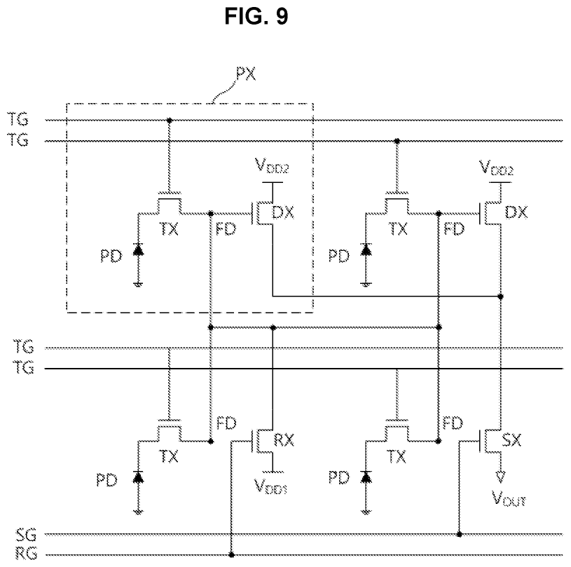

In example embodiments, the transfer gate TG may constitute a transfer transistor TX (see FIG. 9), and the transfer transistor TX may be configured to transfer charges, generated in a photoelectric conversion region 120, to a floating diffusion region FD. The reset gate RG may constitute a reset transistor RX (see FIG. 9), and the reset transistor RX may be configured to periodically reset charges stored in the floating diffusion region FD. The source follower gate SF may constitute a drive transistor DX (see FIG. 9), and the drive transistor DX may serve as a source follower buffer amplifier and may be configured to buffer a signal based on the charges stored in the floating diffusion region FD. The select gate SEL may include a select transistor SX (see FIG. 9), and the select transistor SX may perform switching and addressing operation to select a pixel PX.

As described in the above embodiments, the transfer gate TG may be implemented as a vertical transfer gate electrode VTG having an annular shape of which one side is open. The vertical transfer gate electrode VTG may be disposed in a recess RCS extending inwardly of a semiconductor substrate 110 from a first surface 110F of the semiconductor substrate 110. A gate insulating layer GI may be conformally disposed on the recess RCS, and a vertical transfer gate electrode VTG may fill the recess RCS on the gate insulating layer GI.

For example, a top surface of the vertical transfer gate electrode VTG may be disposed on a level higher than a level of the first surface 110F of the semiconductor substrate 110, and a transfer gate spacer SP may be disposed on a sidewall of the vertical transfer gate electrode VTG.

In example embodiments, the vertical transfer gate electrode VTG may include at least one of doped polysilicon, a metal, a metal silicide, a metal nitride, or a metal-containing layer. The gate insulating layer GI may include a silicon oxide or a metal oxide, and the transfer gate spacer SP may include a silicon nitride, a silicon oxynitride, or a silicon oxide.

The reset gate RG, the source follower gate SF, and the select gate SEL may be referred to as a first gate electrode GE1, and the first gate electrode GE1 is a first surface 110F of the semiconductor substrate 110 may be disposed to surround sidewalls of a semiconductor pattern AP disposed on the first surface 110F of the semiconductor substrate 110. The semiconductor pattern AP and the first gate electrode GE1, surrounding the semiconductor pattern AP, may constitute a gate-all-around transistor.

The semiconductor pattern AP may extend from the first surface 110F of the semiconductor substrate 110 in a vertical direction Z. For example, the semiconductor pattern AP may include one of Si, Ge, SiGe, SiC, GaAs, InAs, or InP.

In some embodiments, the semiconductor pattern AP may include a material layer epitaxially grown using the first surface 110F of the semiconductor substrate 110 as a seed layer. In other embodiments, the semiconductor pattern AP may be a portion of the semiconductor substrate 110, may be formed by forming a mask pattern, not illustrated, on the first surface 110F of the semiconductor substrate 110 and then etching the semiconductor substrate 110 by a predetermined thickness, and may be a portion of the semiconductor substrate 110 remaining to protrude from the first surface 110F of the semiconductor substrate 110 in a third direction (the vertical direction) D3.

In some embodiments, the semiconductor pattern AP may have a circular horizontal cross-section. In some embodiments, the semiconductor pattern AP may have a horizontal cross-section having another shape. For example, in some embodiments, the semiconductor pattern AP may have an elliptical or rectangular horizontal cross-section. As described above, the shape of the horizontal cross-section of the semiconductor pattern AP is not limited thereto.

The first gate electrode GE1 may surround a sidewall of the semiconductor pattern AP on the first surface 110F of the semiconductor substrate 110. For example, the first gate electrode GE1 may include a main electrode portion MP, surrounding a sidewall of the semiconductor pattern AP, and a first extension portion EXP extending from the main electrode portion MP in a parallel direction to be disposed on the first surface 110F of the semiconductor substrate 110. In plan view, the main electrode portion MP may have a ring shape and may surround the entire sidewall of the semiconductor pattern AP.

The extension portion EXP may have a planar top surface level on the first surface 110F of the semiconductor substrate 110 and may be formed to have a predetermined width. A contact (for example, a second contact portion CT2) may be disposed on the extension portion EXP, and thus an electrical signal may be applied to the first gate electrode GE1 through the contact. Since the first gate electrode GE1 includes the extension portion EXP having a planar top surface extending from the main electrode portion MP, defects may be prevented from occurring in a process of forming a contact with the first gate electrode GE1. In example embodiments, the top surface of the extension portion EXP may be disposed on the same level as a top surface of the vertical transfer gate electrode VTG, but example embodiments are not limited thereto.

A first gate insulating layer GI1 may be interposed between the semiconductor pattern AP and the first gate electrode GE1 and may surround a sidewall of the semiconductor pattern AP. The first gate insulating layer GI1 may extend from the sidewall of the semiconductor pattern AP to the first surface 110F of the semiconductor substrate 110, but example embodiments are not limited thereto. The first gate insulating layer GI1 may be formed as a continuous material layer extending inwardly of the recess RCS to be connected to the gate insulating layer GI. In some embodiments, the first gate insulating layer GI1 may extend upwardly of the first surface 110F of the semiconductor substrate 110 without extending inwardly of the recess RCS and may be formed as an insulating layer, independent of the gate insulating layer GI.

The semiconductor pattern AP may be disposed on a first source/drain region SD1, an upper side of the semiconductor pattern AP may not be covered or overlapped with the main electrode portion MP, and a second source/drain region SD2 may be disposed on the upper side of the semiconductor pattern AP.

The first source/drain region SD1 and the second source/drain region SD2 may be heavily doped regions. For example, the semiconductor pattern AP, the main electrode portion MP of the first gate electrode GE1, the first source/drain region SD1, and the second source/drain region SD2 may constitute a gate-all-around transistor.

In example embodiments, the first gate electrode GE1 may include at least one of doped polysilicon, a metal, a metal silicide, a metal nitride, or a metal-containing layer. The first gate insulating layer GI1 may include a silicon oxide or a metal oxide, but example embodiments are not limited thereto.

A vertical insulating layer 124 may be disposed on the first surface 110F of the semiconductor substrate 110. The vertical insulating layer 124 may cover or overlap a ground region GND, a floating diffusion region FD, an isolation layer 112, a vertical transfer gate electrode VTG, the semiconductor pattern AP, and the first gate electrode GE1. The vertical insulating layer 124 may be formed to have a height, sufficient to cover or overlap top surfaces of the semiconductor pattern AP and the first gate electrode GE1.

In example embodiments, the vertical insulating layer 124 may include a silicon nitride or a silicon oxynitride. In some embodiments, the vertical insulating layer 124 may be formed as a stack structure in which a first insulating layer, not illustrated, and a second insulating layer, not illustrated, are stacked. In other embodiments, an etch-stop layer, not illustrated, may be interposed between the vertical insulating layer 124 and the first surface 110F of the semiconductor substrate 110 and may include a material having an etch selectivity with respect to the vertical insulating layer 124.

A contact may be disposed on the first surface 110F of the semiconductor substrate 110 to penetrate through the vertical insulating layer 124. For example, the contact may penetrate through the vertical insulating layer 124 and may be electrically connected to an active region AA, not illustrated, the vertical transfer gate electrode VTG, and the first gate electrode GE1. The contact may include a first contact portion CT1, a second contact portion CT2, and a third contact portion CT3.

The first contact portion CT1 may be disposed in a first contact hole CH1 penetrating through the vertical insulating layer 124. The first contact hole CH1 may expose a top surface of the first surface 110F of the semiconductor substrate 110, and may expose, for example, the ground region GND and the floating diffusion region FD. The first contact portion CT1 may fill partially or completely the first contact hole CH1 and may be connected to the ground region GND and the floating diffusion region FD.

The second contact portion CT2 may be disposed in a second contact hole CH2 penetrating through the vertical insulating layer 124. The second contact hole CH2 may expose a top surface of the vertical transfer gate electrode VTG and a top surface of the first gate electrode GE1. For example, the second contact hole CH2 may expose a top surface of the extension portion EXP of the first gate electrode GE1. The second contact portion CT2 may fill partially or completely the second contact hole CH2 and may be connected to the top surface of the vertical transfer gate electrode VTG and the top surface of the extension EXP of the first gate electrode GE1.

The third contact CT3 may be disposed in a third contact hole CH3 penetrating through the vertical insulating layer 124. The third contact hole CH3 may expose a top surface of the semiconductor pattern AP or a top surface of the second source/drain region SD2. The third contact CT3 may fill partially or completely the third contact hole CH3 and may be connected to the second source/drain region SD2.

An upper interconnection structure, not illustrated, may be disposed on the vertical insulating layer 124. The upper interconnection structure may be formed as a stack structure in which a plurality of layers are stacked. The upper interconnection structure may include an interconnection layer and an insulating layer surrounding the interconnection layer. The interconnection layer may include at least one of polysilicon doped or undoped with impurities, a metal, a metal silicide, a metal nitride, or a metal-containing layer. For example, the interconnection layer may include tungsten, aluminum, copper, a tungsten silicide, a titanium silicide, a tungsten nitride, a titanium nitride, doped polysilicon, or the like. The insulating layer 125 may include an insulating material such as a silicon oxide, a silicon nitride, or a silicon oxynitride.

A separation layer WL may be formed in a trench TCH penetrating through the semiconductor substrate 110 from the first surface 110F to the second surface 110R of the semiconductor substrate 110. The separation layer WL may include a separation insulating layer 122 conformally formed on a sidewall of the trench TCH, a conductive layer CL filling partially or completely the trench TCH on the separation insulating layer 122, and an upper insulating layer 123. The upper insulating layer 123 may be disposed in a portion of the trench TCH adjacent to the first surface 110F of the semiconductor substrate 110. In example embodiments, the upper insulating layer 123 may be formed by a process in which portions of the separation insulating layer 122 and the conductive layer CL, disposed at an entrance of the trench TCH, are etched back and a remaining space is filled partially or completely with an insulating material.

In some embodiments, the separation insulating layer 122 may include a metal oxide such as a hafnium oxide, an aluminum oxide, or a tantalum oxide. In this case, the separation insulating layer 122 may serve as a negative fixed charge layer, but example embodiments are not limited thereto. In other embodiments, the separation insulating layer 122 may include an insulating material such as a silicon oxide, a silicon nitride, or a silicon oxynitride. The conductive layer CL may include at least one of doped polysilicon, a metal, a metal silicide, a metal nitride, or a metal-containing layer.

In some embodiments, the separation layer WL is illustrated as extending from the first surface 110F to the second surface 110R of the semiconductor substrate 110 through the semiconductor substrate 110. However, in other embodiments, the separation layer WL may extend inwardly of the semiconductor substrate 110 from the second surface 110R of the semiconductor substrate 110 and may not be exposed to the first surface 110F of the semiconductor substrate 110. In this case, a barrier doped region, not illustrated, may be formed between the first surface 110F of the semiconductor substrate 110 and one end of the separation layer WL adjacent to the first surface 110F. The barrier doped region may be a region heavily doped with P-type impurities.

In example embodiments, an isolation layer 112 may be formed on the first surface 110F of the semiconductor substrate 110 to define the active region AA, not illustrated. The isolation layer 112 may be disposed in an isolation trench, not illustrated, formed on the first surface 110F of the semiconductor substrate 110 to have a predetermined depth and may include an insulating material. The isolation layer 112 may be disposed to surround an upper sidewall (for example, a sidewall of the upper insulating layer 123) of the separation layer WL.

A rear insulating layer 121 may be disposed on the second surface 110R of the semiconductor substrate 110. The rear insulating layer 121 may be disposed on substantially an entire area of the second surface 110R of the semiconductor substrate 110, and may be in contact with a top surface of the separation layer WL disposed on the same level as the second surface 110R of the semiconductor substrate 110. In some embodiments, the rear insulating layer 121 may include a metal oxide such as a hafnium oxide, an aluminum oxide, or a tantalum oxide. In other embodiments, the rear insulating layer 121 may include an insulating material such as a silicon oxide, a silicon nitride, a silicon oxynitride, or a low-K dielectric material.

A color filter CF and a microlens ML may be disposed on the rear insulating layer 121. Optionally, a support substrate, not illustrated, may be further disposed on the first surface 110F of the semiconductor substrate 110.

In general, pixel circuits such as a reset gate RG, a select gate SEL, and a source follower gate SF, disposed in a pixel PX, may be disposed to be spaced apart from each other in a parallel direction within the pixel PX. As a degree of integration of the image sensor increases, a size of a unit pixel decreases and a size of each component of the pixel circuit also decreases. Therefore, leakage current through the pixel circuit or read noise of the pixel circuit may be generated to deteriorate the quality of an image sensor.

However, according to example embodiments, an image sensor may have a gate-all-around structure in which the semiconductor pattern AP extends in a third direction D3 and the first gate electrode GE1 surrounds the sidewall of the semiconductor pattern AP. Accordingly, the image sensor having the above-mentioned structure may have advantages to reduce leakage current of pixel circuits such as a reset gate RG, a select gate SEL, and a source follower gate SF and to prevent generation of read noise, in addition to advantages of a vertical transfer gate described in the above embodiments. Thus, the image sensor may have improved image quality. In addition, as the semiconductor pattern AP and the first gate electrode GE1 extend in the vertical direction D3, an area of a unit pixel may be reduced and miniaturization of the image sensor may be implemented.

FIG. 9 is an equivalent circuit diagram of a pixel PX of an image sensor according to example embodiments.

Referring to FIG. 9, a plurality of pixels PX may be arranged in a matrix. Each of the plurality of pixels PX may include a transfer transistor TX and logic transistors. The logic transistors may include a reset transistor RX, a select transistor SX, and a drive transistor DX (or a source follower transistor). The reset transistor RX may have a reset gate RG, the select transistor SX may have a select gate SG, the drive transistor DX may have a source follower gate SF, and the transfer transistor TX may have a transfer gate TG.

Each of the plurality of pixels PX may further include a photoelectric conversion element PD and a floating diffusion region FD. The photoelectric conversion element PD may correspond to the above-described photoelectric conversion region. The photoelectric conversion element PD may generate and accumulate photocharges in proportion to intensity of externally incident light, and may employ a photodiode, a phototransistor, a photogate, a pinned photodiode (PPD), or combinations thereof.

The transfer gate TG may transfer charges, generated by the photoelectric conversion element, to the floating diffusion region FD. The floating diffusion region FD may receive and accumulate the charges generated by the photoelectric conversion element PD. The drive transistor DX may be controlled based on an amount of photocharges accumulated in the floating diffusion region FD.

The reset transistor RX may periodically reset the charges accumulated in the floating diffusion region FD. A drain electrode of the reset transistor RX may be connected to the floating diffusion region FD, and a source electrode thereof may be connected to a power supply voltage V_{DD1}. When the reset transistor RX is turned on, the power supply voltage V_{DD1} connected to the source electrode of the reset transistor RX may be transmitted to the floating diffusion region FD. When the reset transistor RX is turned on, the charges accumulated in the floating diffusion region FD may be discharged to reset the floating diffusion region FD. The drive transistor DX may be connected to a current source, not illustrated, disposed outside the plurality of pixels PX, to serve as a source follower buffer amplifier, and may amplify a potential change in the floating diffusion region FD and then output the amplified potential change to an output line V_{OUT}.

The select transistor SX may select a plurality of pixels PX in units of rows, and the power supply voltage V_{DD2} may be transmitted to a source electrode of the drive transistor DX when the select transistor SX is turned on.

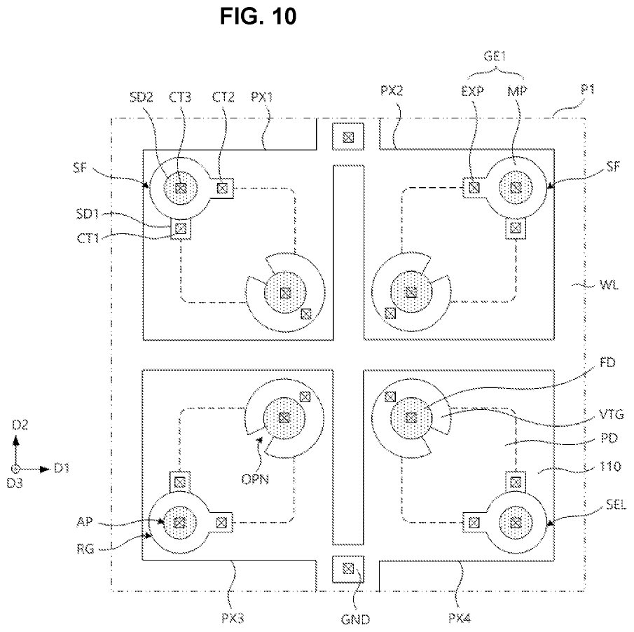

FIG. 10 is a plan view illustrating an image sensor according to example embodiments.

Referring to FIG. 10, in plan view, a separation layer WL may not be disposed to completely surround each of pixels PX1, PX2, PX3, and PX4. A portion of the semiconductor substrate 110, in which the separation layer WL does not surround the pixels PX1, PX2, PX3, and PX4, may be referred to as a sharing region. A ground region GND may be disposed in the sharing region. For example, the ground region GND may be shared by the first pixel PX1 and the second pixel PX2, or may be shared by the third pixel PX3 and the fourth pixel PX4.

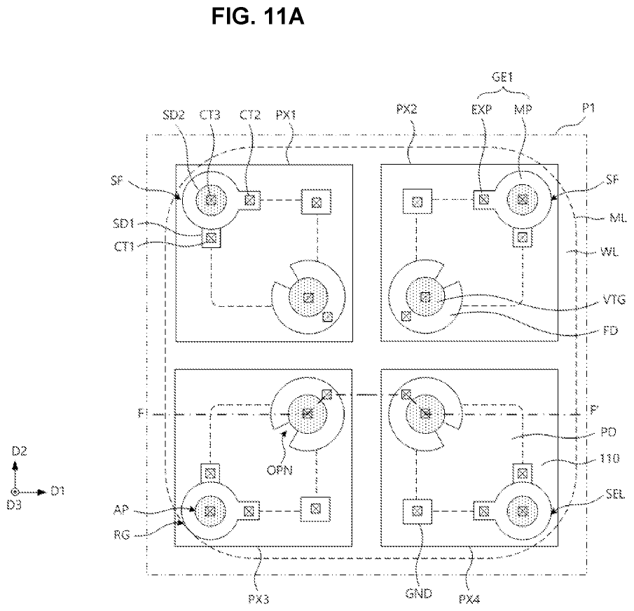

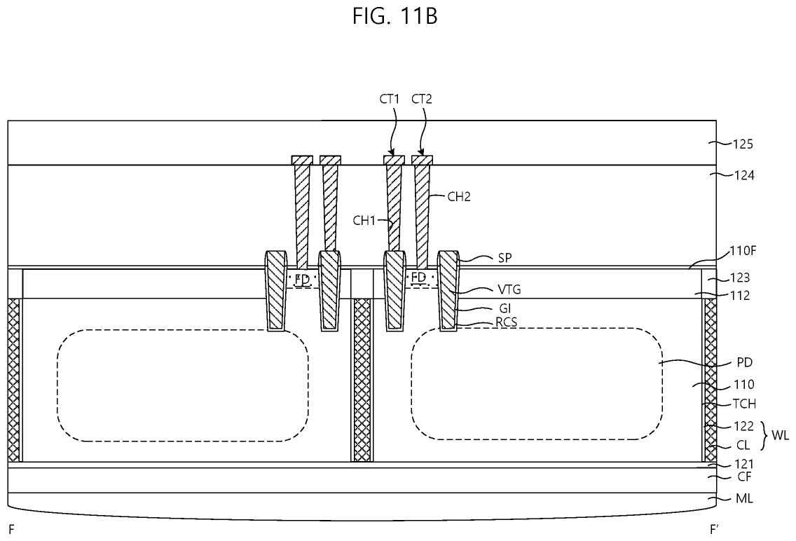

FIG. 11A is a plan view illustrating an image sensor according to example embodiments, and FIG. 11B is a cross-sectional view taken along line F-F′ of FIG. 11A.

Referring to FIGS. 11A and 11B, microlenses of an image sensor may be shared by at least two pixels adjacent to each other. For example, first to fourth pixels PX1, PX2, PX3, and PX4 may be covered with or overlapped by a single microlens ML.

In example embodiments, the image sensor may be configured to implement an autofocusing function. For example, the first to fourth pixels PX1, PX2, PX3, and PX4 may be phase detection pixels. The first to fourth pixels PX1, PX2, PX3, and PX4 may generate phase signals used to calculate a phase difference between images. The first to fourth pixels PX1, PX2, PX3, and PX4 may be used to focus on an object, and the phase signals may include information on positions of images focused on an image sensor 300, and the phase signals may be used to calculate phase differences between images. A focal position of a lens of an electronic device provided with the image sensor 300 may be calculated based on the calculated phase differences.

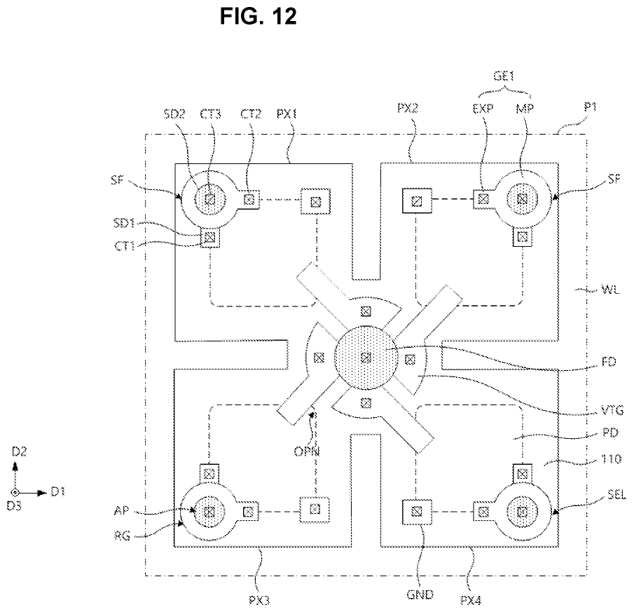

FIG. 12 is a plan view illustrating an image sensor according to example embodiments.

Referring to FIG. 12, a floating diffusion region FD and a vertical transfer gate VTG may be shared by at least two pixels. FIG. 12 illustrates an example in which the floating diffusion region FD and the vertical transfer gate VTG are shared by a first pixel PX1, a second pixel PX2, a third pixel PX3, and a fourth pixel PX4.

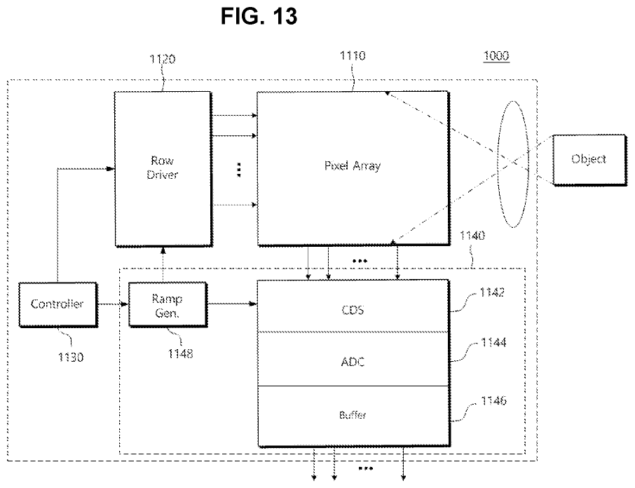

FIG. 13 is a block diagram illustrating a configuration of an image sensor according to example embodiments.

Referring to FIG. 13, an image sensor 1000 may include a pixel array 1110 and a control unit including a controller 1130, a row driver 1120, and a pixel signal processor 1140. The image sensor 1000 includes at least one of the above-described image sensors according to example embodiments.

The pixel array 1110 may include a plurality of two-dimensionally arranged unit pixels, and each of the unit pixels may include an organic photoelectric conversion element. The photoelectric conversion element may absorb light to generate charges, and an electrical signal (an output voltage) based on the generated charges may be provided to the pixel signal processor 1140 through a vertical signal line. Unit pixels, included in the pixel array 1110, may provide output voltages at a time in units of rows, and thus unit pixels belonging to a single row of the pixel array 1110 may be simultaneously activated by a selection signal output by the row driver 1120. Unit pixels, belonging to a selected row, may provide an output voltage based on the absorbed light to an output line of a corresponding column.

The controller 1130 may control the row driver 1120 such that the pixel array 1110 absorbs light to accumulate charges or to temporarily store the accumulated charges and outputs an electrical signal based on the stored charges to an external entity of the pixel array 1110. Also, the controller 1130 may control the pixel signal processor 1140 to measure an output voltage provided by the pixel array 1110.

The pixel signal processor 1140 may include a correlated double sampler (CDS) 1142, an analog-to-digital converter (ADC) 1144, and a buffer 1146. The correlated double sampler 1142 may sample and hold the output voltage provided by the pixel array 1110. The correlated double sampler 1142 may double sample a specific noise level and/or a level based on the generated output voltage, to output a level corresponding to a difference therebetween. Also, the correlated double sampler 1142 may receive ramp signals, generated by a ramp signal generator 1148, and may compare the received ramp signals with each other to output a result of the comparison.

The analog-to-digital converter 1144 may convert an analog signal, corresponding to a level received from the correlated double sampler 1142, into a digital signal. The buffer 1146 may latch digital signals, and the latched signals may be sequentially output to an external entity of the image sensor 1000 and then transmitted to an image processor, not illustrated.

As described above, in an image sensor according to example embodiments, a vertical transfer gate is not provided to a region corresponding to a main transfer path of charges. Therefore, transfer characteristics of the vertical transfer gate may be improved, and transfer delay and image lag may be prevented. In addition, high full-well capacity and a low transfer gate-on voltage may be secured due to improvement of charge transfer capability, and thus a high-quality image sensor may be implemented.

While example embodiments have been shown and described above, it will be apparent to those skilled in the art that modifications and variations could be made without departing from the scope of the present inventive concept as defined by the appended claims.

What is claimed is:

1. An image sensor comprising at least one pixel, wherein the at least one pixel comprises:
a photoelectric conversion region in a semiconductor substrate that has a first surface and a second surface that oppose each other;
a floating diffusion region spaced apart from the photoelectric conversion region in the semiconductor substrate; and
a vertical transfer gate that extends into the semiconductor substrate from the first surface of the semiconductor substrate, wherein a transfer channel is between the photoelectric conversion region and the floating diffusion region,
wherein the vertical transfer gate has an annular shape along a periphery of the floating diffusion region in plan view, and
wherein the vertical transfer gate has an opening that is in a charge transfer path from the photoelectric conversion region to the floating diffusion region.

2. The image sensor of claim 1, wherein the opening overlaps a straight line between the floating diffusion region and a point that represents a maximum potential value, in the photoelectric conversion region.

3. The image sensor of claim 2, wherein the point that represents the maximum potential value is in a central portion of the photoelectric conversion region in the plan view.

4. The image sensor of claim 1, wherein the annular shape of the vertical transfer gate comprises a circular annular shape.

5. The image sensor of claim 1, wherein the annular shape of the vertical transfer gate comprises a rectangular annular shape.

6. The image sensor of claim 1, further comprising:
a separation layer that extends from the first surface of the semiconductor substrate to the second surface of the semiconductor substrate adjacent the at least one pixel.

7. The image sensor of claim 1, wherein the floating diffusion region extends along a portion of a sidewall of the vertical transfer gate, and
wherein a bottom surface of the floating diffusion region is separated from a bottom surface of the vertical transfer gate.

8. The image sensor of claim 6, wherein the separation layer is around at least a portion of a periphery of the at least one pixel in the plan view.

9. The image sensor of claim 1, further comprising:
a microlens on the second surface of the semiconductor substrate.

10. The image sensor of claim 9, wherein the image sensor comprises a plurality of pixels including the at least one pixel, and
wherein the microlens is shared by at least two adjacent pixels of the plurality of pixels.

11. The image sensor of claim 1, wherein the image sensor comprises a plurality of pixels including the at least one pixel, and
wherein the floating diffusion region is shared by at least two adjacent pixels of the plurality of pixels.

12. The image sensor of claim 1, wherein the at least one pixel further comprises a transistor on the semiconductor substrate.

13. The image sensor of claim 1, wherein the semiconductor substrate comprises an active region comprising the at least one pixel, and a peripheral region on at least one side of the active region, and
wherein a pixel circuit is in the peripheral region and is configured to control the at least one pixel.

14. The image sensor of claim 1, wherein the photoelectric conversion region is configured to receive incident light through the second surface of the semiconductor substrate.

15. An image sensor comprising:
a pixel array comprising a plurality of pixels; and
a control unit configured to control the pixel array,
wherein each of the plurality of pixels comprises:
a photoelectric conversion region in a semiconductor substrate that has a first surface and a second surface that oppose each other;
a floating diffusion region spaced apart from the photoelectric conversion region in the semiconductor substrate; and
a vertical transfer gate that extends into the semiconductor substrate from the first surface of the semiconductor substrate,
wherein a transfer channel is between the photoelectric conversion region and the floating diffusion region, and
wherein the vertical transfer gate has an annular shape along a periphery of the floating diffusion region in plan view, and
wherein the vertical transfer gate has an opening that is in a charge transfer path from the photoelectric conversion region to the floating diffusion region.

16. An image sensor comprising a pixel that comprises:
a photoelectric conversion region in a semiconductor substrate;
a floating diffusion region that extends into the semiconductor substrate, wherein the floating diffusion region is spaced apart from the photoelectric conversion region; and
a vertical transfer gate that partially surrounds the floating diffusion region in plan view.

17. The image sensor of claim 16, wherein the floating diffusion region extends into the semiconductor substrate from a top surface of the semiconductor substrate, the image sensor further comprising:
a semiconductor pattern on the top surface of the semiconductor substrate; and
a gate electrode that surrounds the semiconductor pattern in the plan view,
wherein the gate electrode comprises a gate-all-around transistor.

18. The image sensor of claim 17, wherein the gate electrode comprises a main electrode portion and an extension portion having a planar top surface that extends from the main electrode portion.

19. The image sensor of claim 16, wherein a height of the vertical transfer gate is greater than a height of the floating diffusion region with respect to a surface of the semiconductor substrate.

20. The image sensor of claim 16, wherein the vertical transfer gate has an opening that is in a charge transfer path from the photoelectric conversion region to the floating diffusion region.
